(19) United States
(12) Patent Application Publication
(10) Pub. No.: US 2018/0213263 A1
(43) Pub. Date: Jul. 26, 2018

(54) METHOD AND APPARATUS FOR ENCODING AND DECODING IMAGES

(71) Applicant: Nokia Technologies Oy, Espoo (FI)

(72) Inventor: Tero RISSA, Siivikkala (FI)

(21) Appl. No.: 15/744,539

(22) PCT Filed: Jul. 11, 2016
(86) PCT No.: PCT/FI2016/050511

§ 371 Date: Jan. 12, 2018

Related U.S. Application Data
(60) Provisional application No. 62/193,692, filed on Jul. 17, 2015.

(51) Int. Cl. H04N 19/91; H04N 19/645; H04N 19/13; H04N 19/423; H03M 7/30; H03M 7/40

(52) U.S. Cl. CPC H04N 19/91; H04N 19/645; H04N 19/13; H04N 19/34; H03M 7/3079; H03M 7/4012; H04N 19/423

(57) ABSTRACT

There are disclosed various methods and apparatuses for encoding an image. In some embodiments the method comprises selecting a datastream among a first datastream and a second datastream, said first datastream and said second datastream comprising context-decision pairs, said context and decision relating to one or more images or a part of the one or more images. A context-decision pair is obtained from the selected bitstream and also an indication of the selected datastream is obtained. The datastream indication is used to select a set of registers containing parameter values relating to the selected datastream. Parameter values from the selected set of registers are provided to arithmetic encoding to form updated parameter values. Previously updated parameter values are stored to a set of registers indicated by a previous datastream indication, said previously updated parameter values relating to a datastream different than said selected datastream.

### TECHNICAL FIELD

The present invention relates to image compression, more specifically to a method for encoding an image and an apparatus for encoding an image.

### BACKGROUND

This section is intended to provide a background or context to the invention that is recited in the claims. The description herein may include concepts that could be pursued, but are not necessarily ones that have been previously conceived or pursued. Therefore, unless otherwise indicated herein, what is described in this section is not prior art to the description and claims in this application and is not admitted to be prior art by inclusion in this section.

The Joint Photographic Experts Group (JPEG) has published a standard for compressing image data known as the JPEG standard. The JPEG standard uses a discrete cosine transform (DCT) compression algorithm that uses Huffman encoding. To improve compression quality for a broader range of applications, the JPEG has developed the “JPEG 2000 standard” (International Telecommunications Union (ITU) Recommendation T.800, August 2002). The JPEG 2000 standard uses discrete wavelet transform (DWT) and adaptive binary arithmetic coding compression.

### SUMMARY

Various embodiments provide a method and apparatus for encoding images.

Various aspects of examples of the invention are provided in the detailed description.

According to a first aspect, there is provided a method comprising:
selecting a datastream among a first datastream and a second datastream, said first datastream and said second datastream comprising context-decision pairs, said context and decision relating to one or more images or a part of one or more images;
obtaining a context-decision pair from the selected datastream and an indication of the selected datastream;
using the datastream indication to select a set of registers containing parameter values relating to the selected datastream;
providing the parameter values from the selected set of registers to arithmetic encoding to form updated parameter values;
storing previously updated parameter values to a set of registers indicated by a previous datastream indication, said previously updated parameter values relating to a datastream different than said selected datastream.

According to a second aspect, there is provided an apparatus comprising:
a first circuitry configured to select a datastream among a first datastream and a second datastream, said first datastream and said second datastream comprising context-decision pairs, said context and decision relating to one or more images or a part of one or more images;
a second circuitry configured to obtain a context-decision pair from the selected datastream and an indication of the selected datastream;
a third circuitry configured to use the datastream indication to select a set of registers containing parameter values relating to the selected datastream;
a fourth circuitry configured to provide the parameter values from the selected set of registers to arithmetic encoding to form updated parameter values;
a fifth circuitry configured to store previously updated parameter values to a set of registers indicated by a previous datastream indication, said previously updated parameter values relating to a datastream different than said selected datastream.

According to a third aspect, there is provided an apparatus comprising:
means for selecting a datastream among a first datastream and a second datastream, said first datastream and said second datastream comprising context-decision pairs, said context and decision relating to one or more images or a part of one or more images;
obtaining a context-decision pair from the selected datastream and an indication of the selected datastream;
using the datastream indication to select a set of registers containing parameter values relating to the selected datastream;
providing the parameter values from the selected set of registers to arithmetic encoding to form updated parameter values;
storing previously updated parameter values to a set of registers indicated by a previous datastream indication, said previously updated parameter values relating to a datastream different than said selected datastream.

### BRIEF DESCRIPTION OF THE DRAWINGS

For a more complete understanding of example embodiments of the present invention, reference is now made to the following descriptions taken in connection with the accompanying drawings in which:

FIG. 1a shows an image comprising one or more components in accordance to an example embodiment;

FIG. 1b shows an image component comprising a rectangular array of pixels, in accordance to an example embodiment;

FIG. 1c shows an image component divided into tiles, in accordance to an example embodiment;

FIG. 2 illustrates an example of an encoding apparatus and a decoding FIG. 2 illustrates an example of an encoding apparatus and a decoding apparatus, in accordance with an embodiment;

FIG. 3a illustrates computation of a forward transform to the tile-component data in an iterative manner, in accordance with an embodiment;

FIG. 3b illustrates the result of the computation of a forward transform to the tile-component data, in accordance with an embodiment;

FIG. 3c depicts an example of coefficients organized in sign and magnitude bit-planes;

FIG. 4 depicts as a flow diagram an example embodiment of the operation of the apparatus;

FIG. 5 illustrates an example of scanning order of samples of code-blocks, in accordance with an embodiment;

FIGS. 6a and 6b illustrate some details of an arithmetic encoder, in accordance with an embodiment;

FIG. 6c depicts an example of contents of some registers of the arithmetic encoder;

FIG. 7 shows a block diagram of an apparatus according to an example embodiment;

FIG. 8 shows an apparatus according to an example embodiment;

FIG. 9 shows an example of an arrangement for wireless communication comprising a plurality of apparatuses, networks and network elements.

### DETAILED DESCRIPTION OF SOME EXAMPLE EMBODIMENTS

The following embodiments are exemplary. Although the specification may refer to “an”, “one”, or “some” embodiment(s) in several locations, this does not necessarily mean that each such reference is to the same embodiment(s), or that the feature only applies to a single embodiment. Single features of different embodiments may also be combined to provide other embodiments.

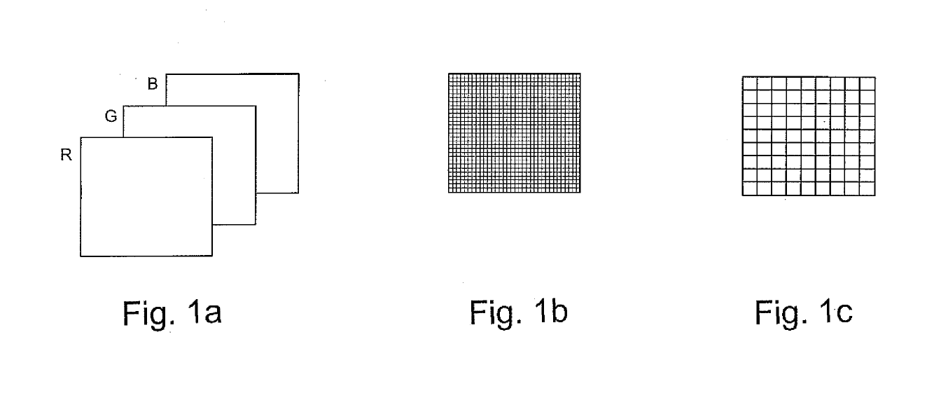

In the following some details of digital images are provided. An image may be comprised of one or more components, as shown in FIG. 1a. Each component may consist of a rectangular array of samples, as is illustrated in FIG. 1b. Sample values for each component may be integers and can either be signed or unsigned with a certain precision, such as from 1 to 38 bits/sample. The signedness and precision of the sample data may be specified on a per-component basis. All of the components are associated with the same spatial extent in the source image, but may represent different spectral or auxiliary information. For example, a RGB (Red-Green-Blue) color image has three components. One of the components represents red color plane, another component represents green color plane, and yet another component represents blue color plane. In a grayscale image there is only one component corresponding to the luminance plane. The various components of an image need not be sampled at the same resolution, wherein the components may have different sizes. For example, when color images are represented in a luminance-chrominance color space, the luminance information may be more finely sampled than the chrominance data.

In some situations, an image may be quite large in comparison to the amount of memory available to the codec. Consequently, it may not always be feasible to code the entire image as a single unit. Therefore, an image may be broken into smaller pieces, each of which may be independently coded. More specifically, an image may be partitioned into one or more disjoint rectangular regions called tiles. An example of such partitioning is depicted in FIG. 1c.

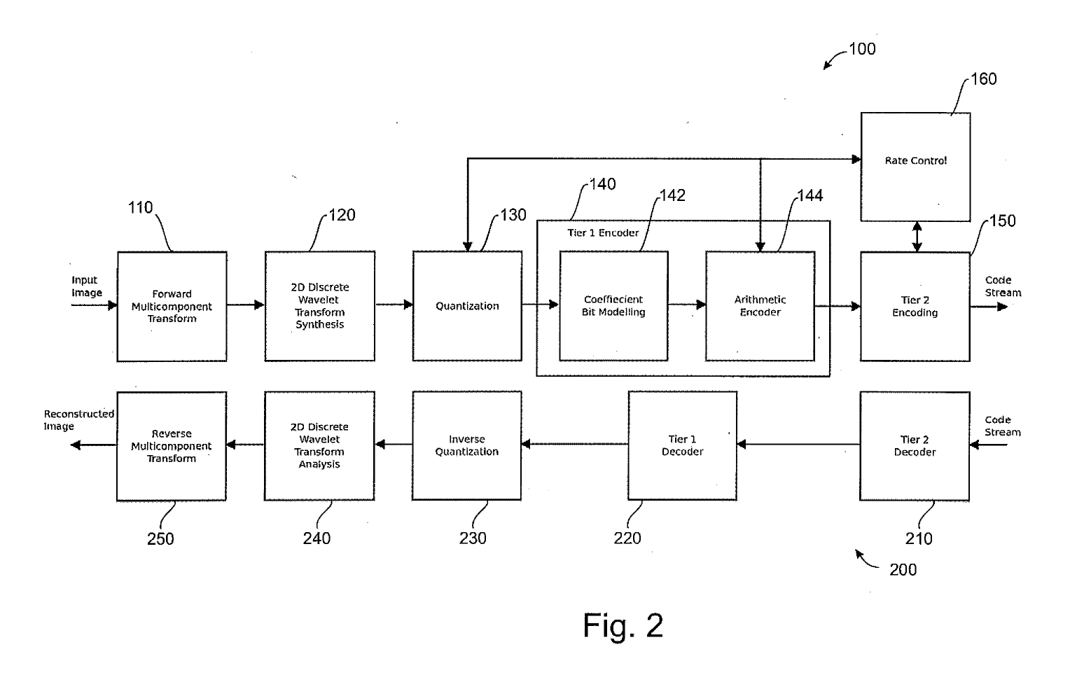

FIG. 2 depicts an example of an encoding apparatus 100 and an example of a decoding apparatus 200 as a simplified block diagrams. The encoder 100 may comprise the following elements: a forward multicomponent transform block 110, an intracomponent transform block 120, a quantization block 130, a tier-1 coding block 140, a tier-2 coding block 150, and a rate control block 160. The decoder structure essentially mirrors that of the encoder. Hence, there may be a one-to-one correspondence between functional blocks in the encoder and decoder. Thus, in accordance with an embodiment and as illustrated in FIG. 2, the following elements may be part of the image decoder 200: a tier-2 decoding block 210, a tier-2 decoding block 220, a dequantization block 230, an inverse intracomponent transform block 240, and a reverse multicomponent transform block 250. Each functional block in the decoder 200 may either exactly or approximately invert the effects of its corresponding block in the encoder 100.

Since tiles may be coded independently of one another, the input image may be processed one tile at a time.

In the following, the operation of each of the above blocks is explained in more detail.

The forward multicomponent transform block 110 may apply a multicomponent transform to the tile-component data. Such a transform may operate on all of the components together, and may serve to reduce the correlation between components, leading to improved coding efficiency.

The multicomponent transforms may be an irreversible color transform (ICT) or a reversible color transform (RCT). The irreversible color transform is nonreversible and real-to-real in nature, while the reversible color transform is reversible and integer-to-integer. Both of these transforms map image data from the RGB to YCrCb color space. The transforms may operate on the first three components of an image, with the assumption that components 0, 1, and 2 correspond to the red, green, and blue color planes. Due to the nature of these transforms, the components on which they operate are sampled at the same resolution. In other words, the components have the same size. After the multicomponent transform stage in the encoder 100, data from each component may be treated independently.

The intracomponent transform block 120 may operate on individual components. An example of the intracomponent transform is the discrete wavelet transform (DWT), wherein the intracomponent transform block 120 may apply a two-dimensional discrete wavelet transform (2D DWT). Another example of intracomponent transform is the change from unsigned number representation to signed number representation, and further example is change to zero DC offset, where the median value is represented with number zero and smallest value with smallest negative number of the range and the largest value with the largest positive value of the range. The discrete wavelet transform splits a component into numerous frequency bands (i.e., subbands). Due to the statistical properties of these subband signals, the transformed data may be coded more efficiently than the original untransformed data. Both reversible integer-to-integer and nonreversible real-to-real discrete wavelet transforms may be employed by the encoder 100. The discrete wavelet transform may apply a number of filter banks to the pre-processed image samples and generate a set of wavelet coefficients for each tile.

Since an image is a two-dimensional (2D) signal, the discrete wavelet transform is applied in both the horizontal and vertical directions. The wavelet transform may then be calculated by recursively applying the two-dimensional discrete wavelet transform to the lowpass subband signal obtained at each level in the decomposition.

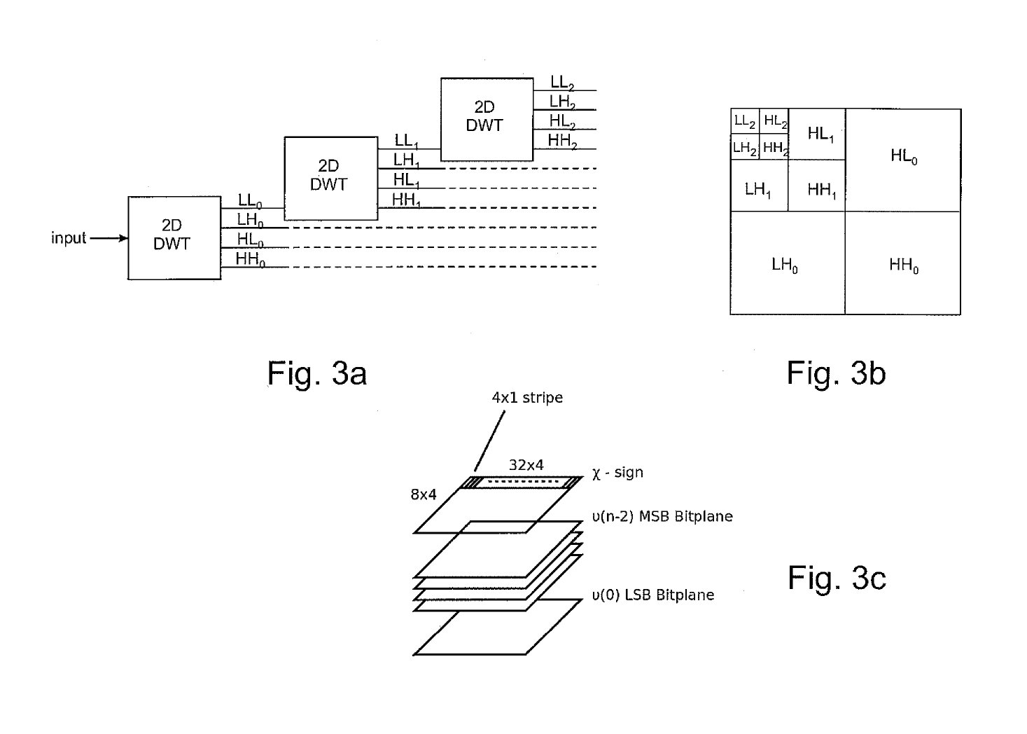

In the following, it is supposed that a (R−1)-level wavelet transform is to be employed. The forward transform may be computed to the tile-component data in an iterative manner, as is illustrated in FIG. 3a, wherein a number of subband signals are produced. Each application of the forward transform yields four subbands: 1) horizontally and vertically lowpass (LL), 2) horizontally lowpass and vertically highpass (LH), 3) horizontally highpass and vertically lowpass (HL), and 4) horizontally and vertically highpass (HH). A (R−1)-level wavelet decomposition is associated with R resolution levels, numbered from 0 to R−1, with 0 and R−1 corresponding to the finest and coarsest resolutions, respectively. Each subband of the decomposition may be identified by its orientation (e.g., LL, LH, HL, HH) and its corresponding resolution level (e.g., 0, 1, . . . , R−1). The input tile-component signal is considered to be the LL₀ band. At each resolution level (except the highest, R−1 level) the LL band may further be decomposed. For example, the LL₀ band is decomposed to yield the LL₁, LH₁, HL₁, and HH₁ bands. Then, at the next level, the LL₁ band is decomposed, and so on. This process may be repeated until the LL_{R-1} band is obtained, and results in the subband structure illustrated in FIG. 3b.

Transformed coefficients may be obtained by the two-dimensional discrete wavelet transform so that a number of coefficients are collected from each repetition as is depicted in FIG. 3a. From the first pass of the discrete wavelet transform coefficients from the horizontally and vertically highpass subband HH₀, coefficients from the horizontally highpass and vertically lowpass subband HL₀, and coefficients from the horizontally lowpass and vertically highpass subband LH₀ may be obtained to represent those subbands. Similarly, from the second pass of the discrete wavelet transform coefficients from the horizontally and vertically highpass subband HH₁, coefficients from the horizontally highpass and vertically lowpass subband HL₁, and coefficients from the horizontally lowpass and vertically highpass subband LH₁ may be obtained to represent the coefficients of those subbands. In the same way, coefficients of three subbands may be obtained from each pass. From the last pass of the discrete wavelet transform coefficients from each subband is obtained, i.e. the horizontally and vertically highpass subband HH₂, the horizontally highpass and vertically lowpass subband HL₂, the horizontally lowpass and vertically highpass subband LH₂, and the horizontally and vertically lowpass subband HH₂.

The bits of the coefficients may be arranged in different bit-planes e.g. as follows. Signs of the coefficients may form a sign layer, the most significant bits (MSB) of the coefficients may form a most significant bit-plane, or layer n−2, if n is the number of bits of the coefficients (including the sign), the next most significant bits of the coefficients may form a next bit-plane, or layer n−3, etc. The least significant bits (LSB) of the coefficients may form a least significant bit-plane, or layer 0. The bit-plane other than the sign layer may also be called as magnitude bit-planes υ(n−2), to υ(0). The sign bit-plane may be called χ. FIG. 3c depicts an example of coefficients organized in bit-planes.

The quantization block 130 quantizes the transformed coefficients obtained by the two-dimensional discrete wavelet transform. Quantization may allow greater compression to be achieved by representing transform coefficients with smaller precision but high enough required to obtain the desired level of image quality. Transform coefficients may be quantized using a scalar quantization. A different quantizer may be employed for the coefficients of each subband, and each quantizer may have only one parameter, a step size. Quantization of transform coefficients may be one source of information loss in the coding path, wherein, in a lossless encoding, the quantization may not be performed. The quantized wavelet coefficients may then be arithmetic coded, for example. Each subband of coefficients may be encoded independently of the other subbands, and a block coding approach may be used.

The coefficients for each subband may be partitioned into code-blocks e.g. in the tier-1 coding block 140. Code-blocks are rectangular in shape, and their nominal size may be a free parameter of the coding process, subject to certain constraints. The nominal width and height of a code-block may be an integer power of two, and the product of the nominal width and height may not exceed a certain value, such as 4096. Since code-blocks are not permitted to cross precinct boundaries, a reduction in the nominal code-block size may be required if the precinct size is sufficiently small. The size of the code-blocks of different subbands may be the same or the size of the code-blocks may be different in different subbands.

The encoding of the code-blocks may also be referred to as coefficient bit modeling (CBM), that may be followed by arithmetic encoding. In context modeling, the coefficients on bit-planes in a code-block may be processed so that a context label is generated for each coefficient in the bit-plane in one of three passes: significance propagation pass (SPP), magnitude refinement pass (MRP), or clean up pass (CU), and each context label is used to describe the context (CX) of that coefficient in that bit-plane. In addition a decision bit (D) is given with each context. A coefficient can become significant in the significance propagation pass or the clean up pass, when the first non-zero magnitude bit is encountered. The significance state of a coefficient bit that has magnitude of 0 (the value of the bit is 0) can anyhow impact to the context of its neighbor coefficients.

After a subband has been partitioned into code-blocks, each of the code-blocks may be independently coded. For each code-block, an embedded code may be produced, comprised of numerous coding passes. The output of the tier-1 encoding process is, therefore, arithmetic encoding of a collection CX-D pairs (from which sign-context-decision pair (SCD-SD) is another example) of coding passes for the various code-blocks. In accordance with an embodiment, the coefficient bit modelling is performed using the parallel single-pass coefficient bit modelling unit described later in this specification.

In the tier-2 coding block 150 code-blocks are grouped into so called precincts. The input to the tier-2 encoding process is the set of bit-plane coding passes generated during tier-1 encoding. In tier-2 encoding, the coding pass information is packaged into data units called packets, in a process referred to as packetization. The resulting packets are then output to the final code stream. The packetization process imposes a particular organization on coding pass data in the output code stream. This organization facilitates many of the desired codec features including rate scalability and progressive recovery by fidelity or resolution.

A packet is a collection of coding pass data comprising e.g. two parts: a header and a body. The header indicates which coding passes are included in the packet, while the body contains the actual coding pass data itself. In a coded bit stream, the header and body need not appear together but they may also be transmitted separately.

Each coding pass is associated with a particular component, resolution level, subband, and code-block. In tier-2 coding, one packet may be generated for each component, resolution level, layer, and precinct 4-tuple. A packet need not contain any coding pass data at all. That is, a packet can be empty. Empty packets may sometimes be needed since a packet should be generated for every component-resolution-layer precinct combination even if the resulting packet conveys no new information.

Since coding pass data from different precincts are coded in separate packets, using smaller precincts reduces the amount of data contained in each packet. If less data is contained in a packet, a bit error is likely to result in less information loss (since, to some extent, bit errors in one packet do not affect the decoding of other packets). Thus, using a smaller precinct size may lead to improved error resilience, while coding efficiency may be degraded due to the increased overhead of having a larger number of packets.

The rate control block 160 may achieve rate scalability through layers. The coded data for each tile is organized into L layers, numbered from 0 to L−1, where L≥1. Each coding pass is either assigned to one of the L layers or discarded. The coding passes containing the most important data may be included in the lower layers, while the coding passes associated with finer details may be included in higher layers. During decoding, the reconstructed image quality may improve incrementally with each successive layer processed. In the case of lossy compression, some coding passes may be discarded, wherein the rate control block 160 may decide which passes to include in the final code stream. In the lossless case, all coding passes should be included. If multiple layers are employed (i.e., L>1), rate control block 160 may decide in which layer each coding pass is to be included. Since some coding passes may be discarded, tier-2 coding may be one source of information loss in the coding path. Rate control can also adjust the quantizer used in the quantization block 130.

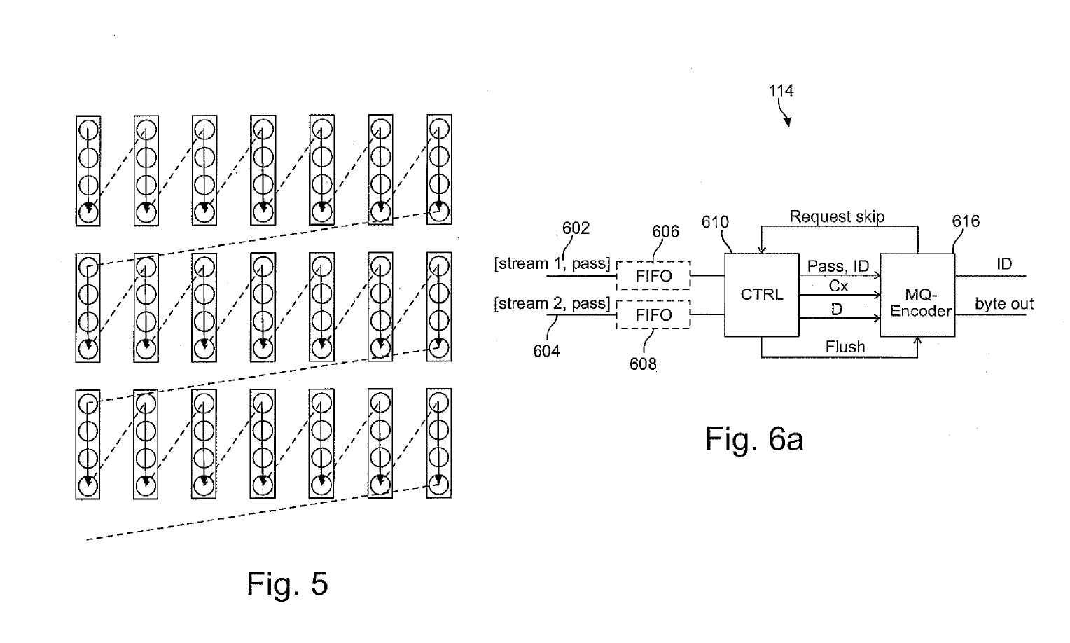

In the following, it is assumed that the size of the code-blocks is 32×32 bits and each DWT coefficient has 11 bits. However, the principles may be implemented with other code-block sizes, such as 64×64 bits, and coefficient sizes different from 11 bits. Furthermore, the code-block need not be square but may also be rectangular. According to the vertical stripe scanning model, samples of code-blocks are scanned in the order illustrated in FIG. 5, namely starting from the top of the left-most column (i e from the top-left corner of the code-block) and scanning the column four samples downwards, then moving to the next four-sample column to the right, scanning the column for the four samples, etc. When the samples of the last, right-most column have been scanned, the process continues from the next four samples of the second column. These four samples of a column can be called as a stripe and a term stripe row may be used for the column, i.e. a collection of stripes in the same rows in each column of the code-block. For example, samples on the first four rows form the first stripe row, samples on the rows five to eight form the second stripe row, etc. When the last stripe row is scanned, then the next code-block may be processed, if needed.

For each coefficient of each bit-plane of the code-block may be assigned a variable called significance state. The significance state value may be, for example, 1, if the sample is significant and 0, if the sample is not significant (i.e. insignificant). In the beginning of the encoding of a code-block the significance state of each sample may be assigned a default value “not significant”. The significance state may then toggle to significant during propagation of the encoding process.

The magnitude bit-planes of the code-block may be examined, beginning e.g. from the most significant magnitude bit-plane in which at least one bit is non-zero (i.e. is one). This bit-plane may be called as a most significant non-zero bit-plane. Then, the scanning of samples of the code-block may be started from the most significant non-zero bit-plane using the vertical stripe scanning model.

An output of context modeling may be a context label Cx and decision D pair for each bit of a stripe and an indication of a pass in which the context was generated.

The context outputs may be input to the arithmetic encoder 144 which encodes the context outputs and provides the encoding result to the tier-2 coding block 150. The rate control block 160 may perform rate control to adjust the amount of data to be transmitted.

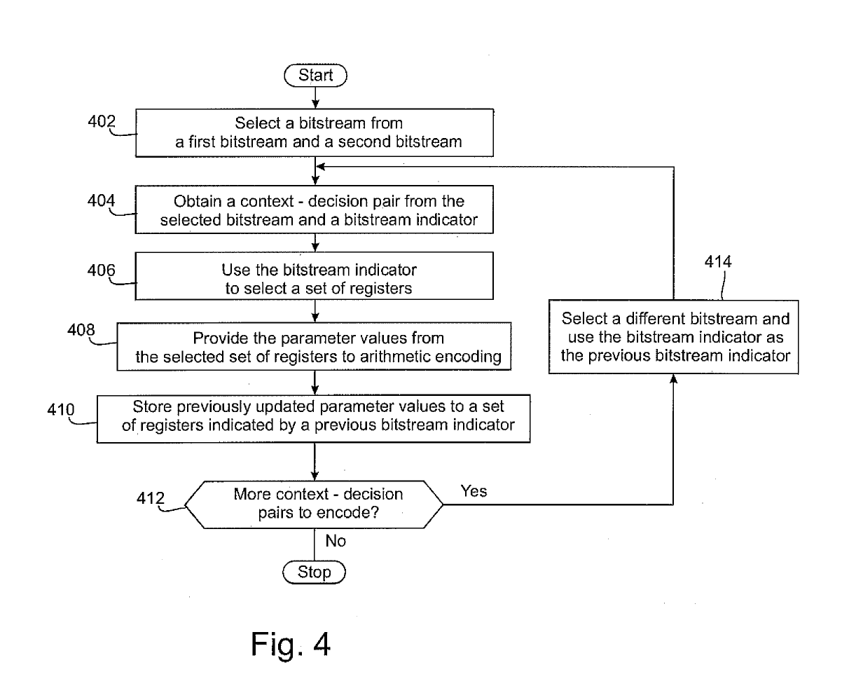

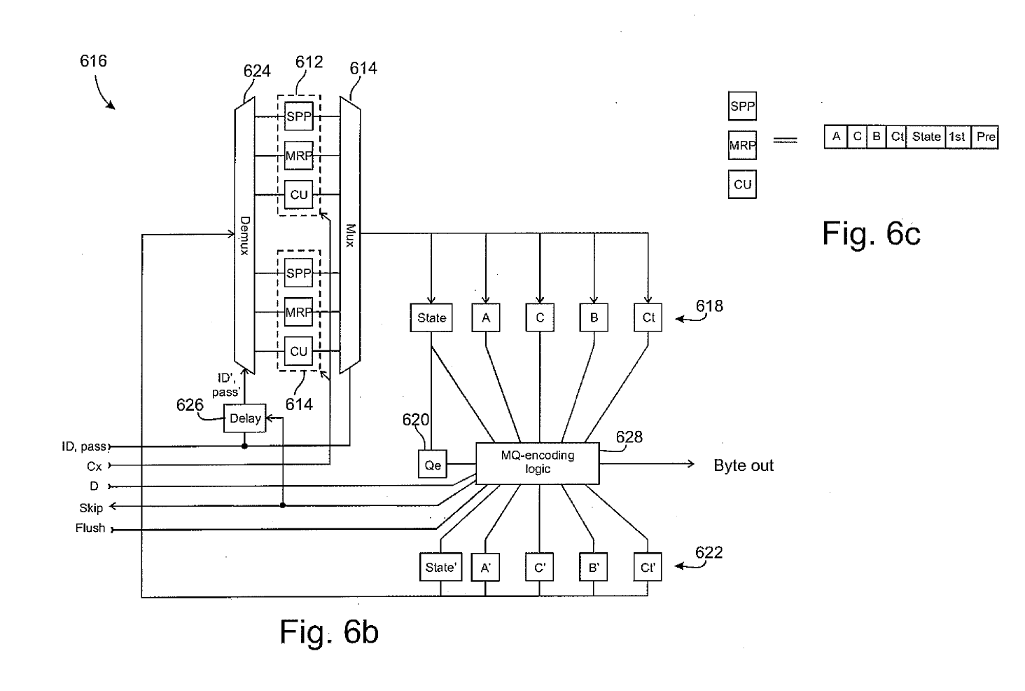

In the following, the operation of the arithmetic encoder 144 will be described in more detail with reference to the block diagrams of FIGS. 6a-6c and the flow diagram of FIG. 4, in accordance with an embodiment. The arithmetic encoder 144 may comprise, for example, a so called MQ-encoder 616.

It is assumed that the arithmetic encoder 144 is able to obtain context label Cx-decision D pairs as two or more independent datastreams. In FIG. 6a this is illustrated with reference numerals 602 and 604. The datastreams may include for each context-decision pair a context label Dx, a decision D, indication of the pass by which the context decision pair was generated and an indication ID of the datastream. The datastreams may be stored into buffers 606, 608, which may be so called first in first out buffers (FIFO). A control block 610 may select 402 one of the datastreams at a time to take 404 a next decision-context pair and corresponding indication of the pass from one of the buffers 606, 608. However, these buffers 606, 608 may not be needed wherein the control block 610 may take from one of the datastreams the next decision-context pair and corresponding indication of the pass. The control block 610 may provide the decision-context pair, the indication ID and pass to the MQ-encoder 616 which may use the indication ID of the datastream and pass to select 406 a register set among different sets of registers 612, 614. The register set includes information of certain parameter values to be used in arithmetic encoding. Those parameters comprise an A value, a C value, a B value, a Ct value and state information. The state comprises information of the current state index of the context label and its Most Probable Symbol (MPS) value. These values will be explained in more detail later in this specification. As an example, if the current indication ID of the datastream indicates that the current context-decision pair was taken from a first datastream 602 and the pass indicates that this pair was generated by a significance propagation pass (SPP), a multiplexer 614 may then be used to select the SPP register from the first register set 612.

The parameters A, C, B, Ct and state are fed 408 to an MQ-encoding logic 628. This is illustrated with blocks 618 in FIG. 6b. The may or may not be registers in between the multiplexer outputs and MQ-encoding logic 628. This may be implementation dependent.

The control block 610 may also use the context label Cx to define the state for the MQ-encoding logic 628. The context label Cx and state may also be used to calculate the Qe value by a Qe calculation logic 620. The Qe calculation logic 620 provides the Qe value, Next Most Probable Symbol (NMPS) index, Next Least Probable Symbol (NLPS) index, and the Switch value. The calculated Qe value, NMPS index, NLPS index, Switch value and the decision D may be provided to the MQ-encoding logic 628 for compressing the current context label Cx and decision D.

When all the above mentioned values are provided to the MQ-encoding logic 628, a state machine of the MQ-encoding logic 628 may proceed further using these values. The results are an updated set of state (state′), an updated A value (A′), an updated C value (C′), an updated B value (B′), and an updated Ct value (Ct′). These values are provided 410 to a demultiplexer 624 which enters these to a correct register set. The register set to be used may be determined by a previous value of the datastream identifier and pass. This is illustrated with a delay block 626 in FIG. 6b. Hence, the updated values are those which were generated on a previous run of the state machine of the MQ-encoding logic 628. In other words, the updated values are based on such previous values, which were related to the same datastream. As explained later, the MQ encoding logic may request a skip from the control block 610. When this happens also the delay block 626 delays further the update operation of the registers 612 and 614.

As an example, if the current indication ID of the datastream indicates that the current context-decision pair was taken from the first datastream 602 and a previous value of the datastream identifier refers to a second datastream 604 and pass refers to a magnitude refinement pass, the updated values may be written to the MRP register of the second set of registers 614.

It may happen that the MQ-encoding logic 628 may not be able to obtain the updated values before it would be time to fetch next context-decision pair for the same datastream. For example, if the state machine of the MQ-encoding logic 628 needs more than one clock cycle to process current values relating to the first datastream, the MQ-encoding logic 628 may generate a request for skip signal to the control block 610 so that the control block 610 will not fetch new context-decision pair from the first datastream 602 but inserts an arbitrary context-decision pair with an ID that indicates it to be ‘empty’ or in otherwise not part of the valid datastream.

Occasionally, the control block 610 may generate a flush signal to the MQ-encoding logic 628 which causes the MQ-encoding logic 628 to perform tasks to terminate encoding of the datastream indicated by the flush signal.

FIG. 6c illustrates values which may be stored by the SPP register, MRP register and the CU register of the register sets 612, 614, in accordance with an embodiment. These include the A, C, B, Ct and state values. They may also comprise a 1^{st} indication and a Pre indication. The 1^{st} indication may be used to indicate if a byte out for this datastream has already occurred or not. This indication may thus be set from a first value (e.g. 0) to a second value (e.g. 1) when the first byte regarding the datastream occurs. The Pre indication indicates whether the received datastreams have already included that datastream to which the register set relates to. This indication may thus be set from a first value (e.g. 0) to a second value (e.g. 1) when the first context-decision pair or a particular datastream has been fetched from the incoming datastreams 602, 604. As an example, if the first set of registers 612 is attached with a first datastream, the Pre indication of the first set of registers 612 is set when the fetched identification ID of the datastream indicates the first datastream.

Possible passes to be performed by the context modelling may include the above mentioned three different kinds of passes. Hence, in accordance with an embodiment, the number of registers in each set of registers 612, 614 may be three (SPP, MRP, CU) and the number of sets may be two or more.

Structures of the A register and C register are described in Table 1, in accordance with an embodiment.

TABLE 1
A and C register structures

| 32-bit register | MSB LSB |
|---|---|
| C (code register) | 0000 cbbb bbbb bsss xxxx xxxx xxxx xxxx |
| A (current interval value) | 0000 0000 0000 0000 aaaa aaaa aaaa aaaa |

In the C register “x” represents fractional bits, “s” represents space bits which provide constraints on carryover and may reduce the probability of carry over propagation in the “b” bits, “b” represents bits of byte out and “c” represents the carry bit.

In the following, the operation of the state machine of the MQ-encoding logic 628 will be illustrated, in accordance with an embodiment. When a context label has been entered to the calculation logic 620, an initial index context look-up table may be examined to find out an initial index value I(Cx) on the basis of the context label (Cx). Table 2 discloses an example of context label-index value relationships.

TABLE 2
Index-Context look-up table

| Operation | Context(CX) | Initial Index I(CX) |
|---|---|---|
| Zero Coding | 0 | 4 |
| | 1 | 0 |
| | 2 | 0 |
| | 3 | 0 |
| | 4 | 0 |
| | 5 | 0 |
| | 6 | 0 |
| | 7 | 0 |
| | 8 | 0 |
| Sign Coding | 9 | 0 |
| | 10 | 0 |
| | 11 | 0 |
| | 12 | 0 |
| | 13 | 0 |
| Magnitude Refinement Coding | 14 | 0 |
| | 15 | 0 |
| | 16 | 0 |
| Run-Length Coding UNIFORM | 17 | 3 |
| | 18 | 46 |

The index obtained from the initial index look-up table may then be used to find out a prediction probability e.g. for a least significant symbol (LSB). This probability may be labelled as Qe. The probability may be obtained from a probability estimate look-up table, which holds the probability estimates for all possible states reached by the encoder. An example of the probability estimate look-up table is shown in Table 3.

There may also be a most probable symbol context look-up table (MPS(Cx)), which may be initialized to all zeros when a new datastream is received. The most probable symbol context look-up table may provide the sense of the more probable symbol (e.g. 1 or 0) of the context Cx.

TABLE 3
A lookup table for Qe value and probability estimation

| Index | Qe | NMPS | NLPS | SWITCH |
|---|---|---|---|---|
| 0 | 0x5601 | 1 | 1 | 1 |
| 1 | 0x3401 | 2 | 6 | 0 |
| 2 | 0x1801 | 3 | 9 | 0 |
| 3 | 0x0AC1 | 4 | 12 | 0 |
| 4 | 0x0521 | 5 | 29 | 0 |
| 5 | 0x0221 | 38 | 33 | 0 |
| 6 | 0x5601 | 7 | 6 | 1 |
| 7 | 0x5401 | 8 | 14 | 0 |
| 8 | 0x4801 | 9 | 14 | 0 |
| 9 | 0x3801 | 10 | 14 | 0 |
| 10 | 0x3001 | 11 | 17 | 0 |
| 11 | 0x2401 | 12 | 18 | 0 |
| 12 | 0x1C01 | 13 | 20 | 0 |
| 13 | 0x1601 | 29 | 21 | 0 |
| 14 | 0x5601 | 15 | 14 | 1 |
| 15 | 0x5401 | 16 | 14 | 0 |
| 16 | 0x5101 | 17 | 15 | 0 |
| 17 | 0x4801 | 18 | 16 | 0 |
| 18 | 0x3801 | 19 | 17 | 0 |
| 19 | 0x3401 | 20 | 18 | 0 |
| 20 | 0x3001 | 21 | 19 | 0 |
| 21 | 0x2801 | 22 | 19 | 0 |
| 22 | 0x2401 | 23 | 20 | 0 |
| 23 | 0x2201 | 24 | 21 | 0 |
| 24 | 0x1C01 | 25 | 22 | 0 |
| 25 | 0x1801 | 26 | 23 | 0 |
| 26 | 0x1601 | 27 | 24 | 0 |
| 27 | 0x1401 | 28 | 25 | 0 |
| 28 | 0x1201 | 29 | 26 | 0 |
| 29 | 0x1101 | 30 | 27 | 0 |
| 30 | 0x0AC1 | 31 | 28 | 0 |
| 31 | 0x09C1 | 32 | 29 | 0 |
| 32 | 0x08A1 | 33 | 30 | 0 |
| 33 | 0x0521 | 34 | 31 | 0 |
| 34 | 0x0441 | 35 | 32 | 0 |
| 35 | 0x02A1 | 36 | 33 | 0 |
| 36 | 0x0221 | 37 | 34 | 0 |
| 37 | 0x0141 | 38 | 35 | 0 |
| 38 | 0x0111 | 39 | 36 | 0 |
| 39 | 0x0085 | 40 | 37 | 0 |
| 40 | 0x0049 | 41 | 38 | 0 |
| 41 | 0x0025 | 42 | 39 | 0 |
| 42 | 0x0015 | 43 | 40 | 0 |
| 43 | 0x0009 | 44 | 41 | 0 |
| 44 | 0x0005 | 45 | 42 | 0 |
| 45 | 0x0001 | 45 | 43 | 0 |
| 46 | 0x5601 | 46 | 46 | 0 |

In addition to the probability estimation, the probability estimate look-up table also comprises columns for next indices for most probable symbols (NMPS) and least probable symbols (NLPS), and a switch value. NMPS(I(CX)) and NLPS(I(CX)) may be used to identify next MPS/LPS index values respectively, and the SWITCH(I(CX)) may indicate if the sense of MPS(CX) has to be inverted.

The MQ-encoding logic 628 may also comprise an A register and a C register and buffers for storing certain A values and C values. Structures of the A register and C register may be similar to the registers described above in Table 1.

In the beginning of the datastream, the context label value is used as an index to the index context look-up table, wherein an initial index value may be obtained. The initial index value may then be used as an index to the probability estimate look-up table to find out the prediction probability Qe for the current context Cx.

After that, a state machine of the MQ-encoding logic 628 may be used to compress the context label and decision into a compressed datastream.

The state machine may comprise e.g. the following operations. It is assumed that the interval used is [0, 1,5), wherein the length of a half of the interval is 0,75. Hence, the A register may be initialized to the length value (0x8000 in this example corresponding to the upper limit of the interval) and the C register may be initialized to 0x0000. The value of the A register is designed to remain within 0.75≤A≤1.5. If the value of the A register falls below the lower limit, it may be corrected by left shifting the A register. This procedure may be called as renormalization. In this case also the C register will be shifted to the left equal number of times.

The decision value may then be used to decide whether a most probable symbol coding or a least probable symbol coding will be used for the current context label decision pair. For example, if the decision indicates a 0-value and the most probable symbol is 0, the most probable symbol coding may be performed. As another example, if the decision indicates a 0-value and the most probable symbol is 1, the least probable symbol coding may be performed.

The most probable symbol coding may comprise the following. The value of the A register will be decremented by the probability value Qe. If the new A register value falls below a minimum (e.g. the above mentioned 0.75 (0x8000), it may further be checked whether the value of the A register is smaller than the probability value Qe. If so, the A register is set equal to the probability value. If the value of the A register is not smaller than the probability value Qe, the C register will be incremented by the probability value Qe. An MPS renormalization process may then occur. If, however, the A register value remained above the minimum after decrementing the probability value Qe from the A register, renormalization is not needed and the C register value is added with the probability value Qe.

On the other hand, the least probable symbol coding may comprise the following. The value of the A register will be decremented by the probability value Qe. If the new A register value is smaller than the probability value Qe, the C register is added with the probability value Qe. If the value of the A register is not smaller than the probability value Qe, the A register will be set equal to the value of the C register. Irrespective of whether decrementing the A register with the probability value Qe resulted that the value of the A register became smaller than the probability value Qe, an LPS renormalization process may then occur.

The MPS renormalization may comprise e.g. the following. The A register is shifted to the left so many times that the A register is not smaller than the minimum. The C register is also shifted to the left equal number of times. The value of the Ct register is also decremented by one when a left shift occurs. When the Ct register becomes 0, the content of the “b”-bits of the C register may then be moved to the B register as a new byte out. A new context index may be fetched from the probability estimate look-up table using the current index as a pointer to the look-up table. The value from the NMPS column indicates the new index for the current context.

Furthermore, a new probability value Qe may also be fetched from the same look-up table using the new index as a pointer to the table, wherein the Qe column indicates the new value for the probability.

The LPS renormalization may comprise e.g. the following. The A register is shifted to the left so many times that the A register is not smaller than the minimum. The C register is also shifted to the left equal number of times. The value of the Ct register is also decremented by one when a left shift occurs. When the Ct register becomes 0, the content of the “b”-bits of the C register may then be moved to the B register as a new byte out. A new context index may be fetched from the probability estimate look-up table using the current index as a pointer to the look-up table. The value from the NMPS column indicates the new index for the current context. Furthermore, a new probability value Qe may also be fetched from the same look-up table using the new index as a pointer to the table, wherein the Qe column indicates the new value for the probability.

The updated values of the A register (A′), C register (C′), B register (B′) and Ct register (Ct′) may be stored to wait for a next compression round for the same datastream, as was described earlier in this specification.

Next, another context label-decision pair from another datastream may be fetched 414 and the process described above may be repeated until no more context label-decision pair are left in the datastreams (this is illustrated with block 412 in FIG. 4).

In accordance with an embodiment, there may be more than two datastreams and corresponding sets of registers 612, 614 and inputs in the multiplexer 614. Also the demultiplexer 624 may hence need a corresponding number of outputs. Also the number of delays 626 may be increased so that the updated values will be stored a correct set of registers 612, 614.

When a byte out occurs the MQ-encoder may output the byte and indication of the datastream to which the newest byte belongs. The byte may be stored to a compressed datastream buffer (not shown) from which the compressed information may be accessed when ready. The datastream indicator may be used to select the compressed datastream buffer which corresponds with the datastream, if a separate buffer has been reserved for separate datastreams, or the datastream indication may be attached with the stored byte to indicate the datastream to which that byte belongs.

As was already mentioned above, the decoder 200 may perform decoding operations which may mainly correspond to inverse operations of the encoder 100. The encoded code stream may be received and provided to the tier-2 decoding block 210 to form reconstructed arithmetic code words. These code words may be decoded by the tier-1 decoding block 220. The resulting reconstructed quantized coefficient values may be dequantized by the dequantization block 230 to produce reconstructed dequantized coefficient values. These may be inverse transformed by the inverse intracomponent transform block 240 and the inverse multicomponent transform block 250 to produce reconstructed pixel values of the encoded image.

The architecture of the apparatus 100 and/or 200 may be realized e.g. as a general purpose field programmable gate array (FPGA), application specific instruction set processor (ASIP), an application specific integrated circuit (ASIC) implementation or other kind of integrated circuit implementation, or any combination of these, which performs the procedures described above.

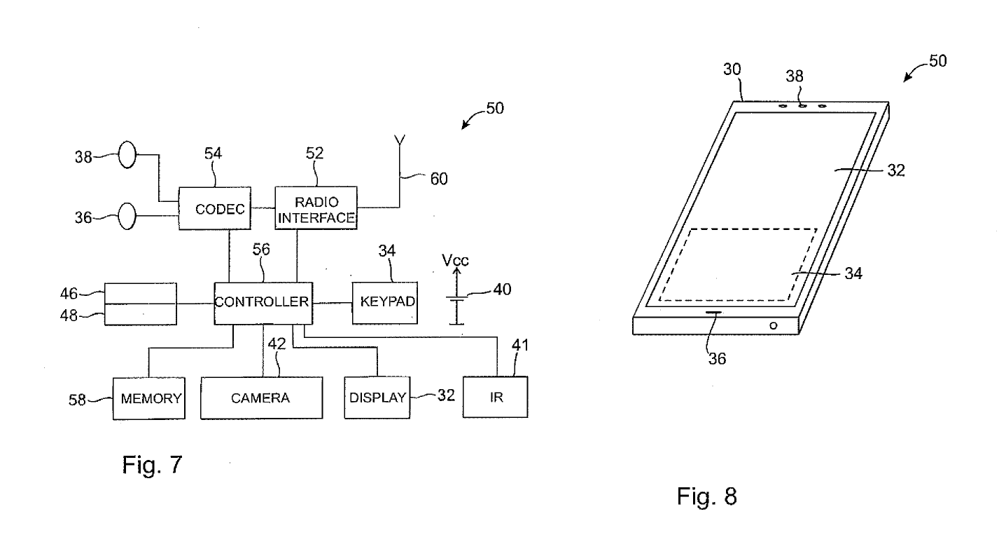

The following describes in further detail suitable apparatus and possible mechanisms for implementing the embodiments of the invention. In this regard reference is first made to FIG. 7 which shows a schematic block diagram of an exemplary apparatus or electronic device 50 depicted in FIG. 8, which may incorporate a transmitter according to an embodiment of the invention.

The electronic device 50 may for example be a mobile terminal or user equipment of a wireless communication system. However, it would be appreciated that embodiments of the invention may be implemented within any electronic device or apparatus which may require transmission of radio frequency signals.

The apparatus 50 may comprise a housing 30 for incorporating and protecting the device. The apparatus 50 further may comprise a display 32 in the form of a liquid crystal display. In other embodiments of the invention the display may be any suitable display technology suitable to display an image or video. The apparatus 50 may further comprise a keypad 34. In other embodiments of the invention any suitable data or user interface mechanism may be employed. For example the user interface may be implemented as a virtual keyboard or data entry system as part of a touch-sensitive display. The apparatus may comprise a microphone 36 or any suitable audio input which may be a digital or analogue signal input. The apparatus 50 may further comprise an audio output device which in embodiments of the invention may be any one of: an earpiece 38, speaker, or an analogue audio or digital audio output connection. The apparatus 50 may also comprise a battery 40 (or in other embodiments of the invention the device may be powered by any suitable mobile energy device such as solar cell, fuel cell or clockwork generator). The term battery discussed in connection with the embodiments may also be one of these mobile energy devices. Further, the apparatus 50 may comprise a combination of different kinds of energy devices, for example a rechargeable battery and a solar cell. The apparatus may further comprise an infrared port 41 for short range line of sight communication to other devices. In other embodiments the apparatus 50 may further comprise any suitable short range communication solution such as for example a Bluetooth wireless connection or a USB/firewire wired connection.

The apparatus 50 may comprise a controller 56 or processor for controlling the apparatus 50. The controller 56 may be connected to memory 58 which in embodiments of the invention may store both data and/or may also store instructions for implementation on the controller 56. The controller 56 may further be connected to codec circuitry 54 suitable for carrying out coding and decoding of audio and/or video data or assisting in coding and decoding carried out by the controller 56.

The apparatus 50 may further comprise a card reader 48 and a smart card 46, for example a UICC reader and UICC for providing user information and being suitable for providing authentication information for authentication and authorization of the user at a network.

The apparatus 50 may comprise radio interface circuitry 52 connected to the controller and suitable for generating wireless communication signals for example for communication with a cellular communications network, a wireless communications system or a wireless local area network. The apparatus 50 may further comprise an antenna 60 connected to the radio interface circuitry 52 for transmitting radio frequency signals generated at the radio interface circuitry 52 to other apparatus(es) and for receiving radio frequency signals from other apparatus(es).

In some embodiments of the invention, the apparatus 50 comprises a camera 42 capable of recording or detecting imaging.

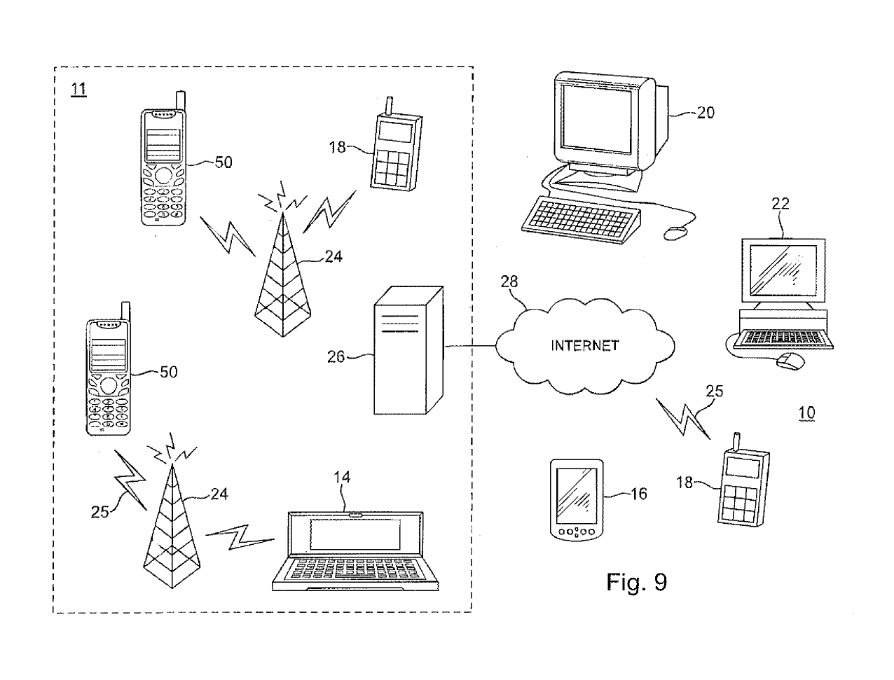

With respect to FIG. 9, an example of a system within which embodiments of the present invention can be utilized is shown. The system 10 comprises multiple communication devices which can communicate through one or more networks. The system 10 may comprise any combination of wired and/or wireless networks including, but not limited to a wireless cellular telephone network (such as a global systems for mobile communications (GSM), universal mobile telecommunications system (UMTS), code division multiple access (CDMA) network etc.), a wireless local area network (WLAN) such as defined by any of the IEEE 802.x standards, a Bluetooth personal area network, an Ethernet local area network, a token ring local area network, a wide area network, and the Internet.

For example, the system shown in FIG. 9 shows a mobile telephone network 11 and a representation of the internet 28. Connectivity to the internet 28 may include, but is not limited to, long range wireless connections, short range wireless connections, and various wired connections including, but not limited to, telephone lines, cable lines, power lines, and similar communication pathways.

The example communication devices shown in the system 10 may include, but are not limited to, an electronic device or apparatus 50, a combination of a personal digital assistant (PDA) and a mobile telephone 14, a PDA 16, an integrated messaging device (IMD) 18, a desktop computer 20, a notebook computer 22, a tablet computer. The apparatus 50 may be stationary or mobile when carried by an individual who is moving. The apparatus 50 may also be located in a mode of transport including, but not limited to, a car, a truck, a taxi, a bus, a train, a boat, an airplane, a bicycle, a motorcycle or any similar suitable mode of transport.

Some or further apparatus may send and receive calls and messages and communicate with service providers through a wireless connection 25 to a base station 24. The base station 24 may be connected to a network server 26 that allows communication between the mobile telephone network 11 and the internet 28. The system may include additional communication devices and communication devices of various types.

The communication devices may communicate using various transmission technologies including, but not limited to, code division multiple access (CDMA), global systems for mobile communications (GSM), universal mobile telecommunications system (UMTS), time divisional multiple access (TDMA), frequency division multiple access (FDMA), transmission control protocol-internet protocol (TCP-IP), short messaging service (SMS), multimedia messaging service (MMS), email, instant messaging service (IMS), Bluetooth, IEEE 802.11, Long Term Evolution wireless communication technique (LTE) and any similar wireless communication technology. A communications device involved in implementing various embodiments of the present invention may communicate using various media including, but not limited to, radio, infrared, laser, cable connections, and any suitable connection. In the following some example implementations of apparatuses utilizing the present invention will be described in more detail.

Although the above examples describe embodiments of the invention operating within a wireless communication device, it would be appreciated that the invention as described above may be implemented as a part of any apparatus comprising a circuitry in which radio frequency signals are transmitted and received. Thus, for example, embodiments of the invention may be implemented in a mobile phone, in a base station, in a computer such as a desktop computer or a tablet computer comprising radio frequency communication means (e.g. wireless local area network, cellular radio, etc.).

In general, the various embodiments of the invention may be implemented in hardware or special purpose circuits or any combination thereof. While various aspects of the invention may be illustrated and described as block diagrams or using some other pictorial representation, it is well understood that these blocks, apparatus, systems, techniques or methods described herein may be implemented in, as non-limiting examples, hardware, software, firmware, special purpose circuits or logic, general purpose hardware or controller or other computing devices, or some combination thereof.

Embodiments of the inventions may be practiced in various components such as integrated circuit modules. The design of integrated circuits is by and large a highly automated process. Complex and powerful software tools are available for converting a logic level design into a semiconductor circuit design ready to be etched and formed on a semiconductor substrate.

Programs, such as those provided by Synopsys, Inc. of Mountain View, Calif. and Cadence Design, of San Jose, Calif. automatically route conductors and locate components on a semiconductor chip using well established rules of design as well as libraries of pre stored design modules. Once the design for a semiconductor circuit has been completed, the resultant design, in a standardized electronic format (e.g., Opus, GDSII, or the like) may be transmitted to a semiconductor fabrication facility or “fab” for fabrication.

The foregoing description has provided by way of exemplary and non-limiting examples a full and informative description of the exemplary embodiment of this invention. However, various modifications and adaptations may become apparent to those skilled in the relevant arts in view of the foregoing description, when read in conjunction with the accompanying drawings and the appended claims. However, all such and similar modifications of the teachings of this invention will still fall within the scope of this invention.

In the following some examples will be provided.

According to a first example, there is provided a method comprising:
selecting a datastream among a first datastream and a second datastream, said first datastream and said second datastream comprising context-decision pairs, said context and decision relating to one or more images or a part of one or more images;
obtaining a context-decision pair from the selected datastream and an indication of the selected datastream;
using the datastream indication to select a set of registers containing parameter values relating to the selected datastream;
providing the parameter values from the selected set of registers to arithmetic encoding to form updated parameter values;
storing previously updated parameter values to a set of registers indicated by a previous datastream indication, said previously updated parameter values relating to a datastream different than said selected datastream.

In accordance with an embodiment, the method further comprises:
storing said magnitude bits of two or more coefficients into a magnitude matrix.

In accordance with an embodiment, the method further comprises:
obtaining an indication of a pass among a set of passes by which the context-decision pair has been generated; and
using the indication to select a register corresponding to the pass among said selected set of registers,
wherein the parameter values are provided from the selected register of said selected set of registers.

In accordance with an embodiment, the method further comprises:
obtaining an indication of a pass among a set of passes by which the previously updated parameter values are related to; and
using the pass indication to select a register corresponding to the pass among said set of registers indicated by the previous datastream indication.
wherein the previously updated parameter values are stored to the selected register of said set of registers indicated by the previous datastream indication.

In accordance with an embodiment, the method further comprises:
selecting the context-decision pair from the first datastream;
selecting a next context-decision pair from the second datastream.

According to a second example, there is provided an apparatus comprising:
a first circuitry configured to select a datastream among a first datastream and a second datastream, said first datastream and said second datastream comprising context-decision pairs, said context and decision relating to one or more images or a part of the one or more images;
a second circuitry configured to obtain a context-decision pair from the selected datastream and an indication of the selected datastream;
a third circuitry configured to use the datastream indication to select a set of registers containing parameter values relating to the selected datastream;
a fourth circuitry configured to provide the parameter values from the selected set of registers to arithmetic encoding to form updated parameter values;
a fifth circuitry configured to store previously updated parameter values to a set of registers indicated by a previous datastream indication, said previously updated parameter values relating to a datastream different than said selected datastream.

According to a third example, there is provided an apparatus comprising:
means for selecting a datastream among a first datastream and a second datastream, said first datastream and said second datastream comprising context-decision pairs, said context and decision relating to one or more images or a part of the one or more images;
obtaining a context-decision pair from the selected datastream and an indication of the selected datastream;
using the datastream indication to select a set of registers containing parameter values relating to the selected datastream;
providing the parameter values from the selected set of registers to arithmetic encoding to form updated parameter values;
storing previously updated parameter values to a set of registers indicated by a previous datastream indication, said previously updated parameter values relating to a datastream different than said selected datastream.

1. A method comprising:
selecting a datastream among a first datastream and a second datastream, said first datastream and said second datastream comprising context-decision pairs, said context and decision relating to one or more images or a part of one or more images;
obtaining a context-decision pair from the selected datastream and an indication of the selected datastream;
using the datastream indication to select a set of registers containing parameter values relating to the selected datastream;
providing the parameter values from the selected set of registers to arithmetic encoding to form updated parameter values; and
storing previously updated parameter values to a set of registers indicated by a previous datastream indication, said previously updated parameter values relating to a datastream different than said selected datastream.

2. The method according to claim 1 further comprising:
storing magnitude bits of two or more coefficients into a magnitude matrix.

3. The method according to claim 1 further comprising:
obtaining an indication of a pass among a set of passes by which the context-decision pair has been generated; and
using the pass indication to select a register corresponding to the pass among said selected set of registers,
wherein the parameter values are provided from the selected register of said selected set of registers.

4. The method according to claim 1 further comprising:
obtaining an indication of a pass among a set of passes by which the previously updated parameter values are related to; and
using the pass indication to select a register corresponding to the pass among said set of registers indicated by the previous datastream indication,
wherein the previously updated parameter values are stored to the selected register of said set of registers indicated by the previous datastream indication.

5. The method according to claim 3, wherein:
the set of passes comprises a significance propagation pass, a magnitude refinement pass, and a clean up pass.

6. The method according to claim 1 further comprising:
selecting the context-decision pair from the first datastream; and
selecting a next context-decision pair from the second datastream.

7. An apparatus comprising:
a first circuitry configured to select a datastream among a first datastream and a second datastream, said first datastream and said second datastream comprising context-decision pairs, said context and decision relating to one or more images or a part of the one or more images;
a second circuitry configured to obtain a context-decision pair from the selected datastream and an indication of the selected datastream;
a third circuitry configured to use the datastream indication to select a set of registers containing parameter values relating to the selected datastream;
a fourth circuitry configured to provide the parameter values from the selected set of registers to arithmetic encoding to form updated parameter values; and
a fifth circuitry configured to store previously updated parameter values to a set of registers indicated by a previous datastream indication, said previously updated parameter values relating to a datastream different than said selected datastream.

8. The apparatus according to claim 7 further comprising:
a memory for storing said magnitude bits of two or more coefficients into a magnitude matrix.

9. The apparatus according to claim 7 further comprising:
a sixth circuitry configured to obtain an indication of a pass among a set of passes by which the context-decision pair has been generated;
wherein said third circuitry configured to use the pass indication to select a register corresponding to the pass among said selected set of registers, and
said fourth circuitry configured to provide the parameter values from the selected register of said selected set of registers.

10. The apparatus according to claim 7 further comprising:
a seventh circuitry configured to obtain an indication of a pass among a set of passes by which the previously updated parameter values are related to;
an eighth circuitry configured to use the pass indication to select a register corresponding to the pass among said set of registers indicated by the previous datastream indication, and
a ninth circuitry configured to store the previously updated parameter values to the selected register of said set of registers indicated by the previous datastream indication.

11. The apparatus according to claim 7, wherein:
said first circuitry being configured to select the context-decision pair from the first datastream; and to select a next context-decision pair from the second datastream.

12.-16. (canceled)
